(19) United States
(12) Patent Application Publication
(10) Pub. No.: US 2020/0098692 A1
(43) Pub. Date: Mar. 26, 2020

(54) MICROELECTRONIC ASSEMBLIES HAVING NON-RECTILINEAR ARRANGEMENTS

(71) Applicant: Intel Corporation, Santa Clara, CA (US)

(72) Inventors: Shawna M. Liff, Scottsdale, AZ (US); Adel A. Elsherbini, Chandler, AZ (US); Johanna M. Swan, Scottsdale, AZ (US)

(73) Assignee: Intel Corporation, Santa Clara, CA (US)

(21) Appl. No.: 16/142,233

(22) Filed: Sep. 26, 2018

(51) Int. Cl. H01L 23/538; H01L 25/065; H01L 23/00; H01L 25/00

(52) U.S. Cl. CPC H01L 23/5385; H01L 23/5386; H01L 25/0655; H01L 24/16; H01L 24/17; H01L 2224/16235; H01L 23/5381; H01L 2224/16227; H01L 2224/1703; H01L 2224/17164; H01L 25/50

(57) ABSTRACT

Microelectronic assemblies, and related devices and methods, are disclosed herein. For example, in some embodiments, a microelectronic assembly may include a bridge structure having a surface; a first die coupled to the surface of the bridge structure by first interconnects, where the first die at least partially overlaps the bridge structure and is non-rectilinear to the bridge structure; and a second die coupled to the surface of the bridge structure by second interconnects, where the second die at least partially overlaps the bridge structure.

### BACKGROUND

Integrated circuit (IC) dies are conventionally coupled to a package substrate for mechanical stability and to facilitate connection to other components, such as circuit boards. The interconnect pitch achievable by conventional substrates is constrained by manufacturing, materials, and thermal considerations, among others.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a top view of an example arrangement of multiple dies and a bridge structure in a microelectronic assembly, in accordance with various embodiments.

FIG. 1B is a side, cross-sectional view of the microelectronic assembly of FIG. 1A, in accordance with various embodiments.

FIG. 2A is a top view of an example arrangement of multiple dies and a bridge structure in a microelectronic assembly, in accordance with various embodiments.

FIG. 2B is a side, cross-sectional view of the microelectronic assembly of FIG. 2A, in accordance with various embodiments.

FIG. 3A is a top view of an example arrangement of multiple dies and a bridge structure in a microelectronic assembly, in accordance with various embodiments.

FIG. 3B is a side, cross-sectional view of the microelectronic assembly of FIG. 3A, in accordance with various embodiments.

FIGS. 4A-4C are top views of example arrangements of multiple dies and a bridge structure in microelectronic assemblies, in accordance with various embodiments.

FIGS. 5A-5C are top views of example arrangements of multiple dies and a bridge structure in microelectronic assemblies, in accordance with various embodiments.

FIG. 6A is a top view of an example arrangement of multiple dies and a bridge structure in microelectronic assembly, in accordance with various embodiments.

FIG. 6B is a side, cross-sectional view of the microelectronic assembly of FIG. 6A, in accordance with various embodiments.

FIGS. 7A-7B are side, cross-sectional views of example microelectronic assemblies, in accordance with various embodiments.

FIG. 8 is a top view of a wafer and dies that may be included in a microelectronic assembly, in accordance with any of the embodiments disclosed herein.

FIG. 9 is a cross-sectional side view of an IC device that may be included in a microelectronic assembly, in accordance with any of the embodiments disclosed herein.

FIG. 10 is a cross-sectional side view of an IC device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Microelectronic assemblies, and related devices and methods, are disclosed herein. For example, in some embodiments, a microelectronic assembly may include a microelectronic assembly may include a bridge structure having a surface; a first die coupled to the surface of the bridge structure by first interconnects, where the first die at least partially overlaps the bridge structure and is non-rectilinear to the bridge structure; and a second die coupled to the surface of the bridge structure by second interconnects, where the second die at least partially overlaps the bridge structure.

Communicating large numbers of signals between two or more dies in a multi-die IC package is challenging due to the increasingly small size of such dies, thermal constraints, and power delivery constraints, among others. Some conventional packages may include two or more active dies (i.e., two or more semiconductor devices, such as processors, controllers, logic devices, and memory devices) that are stacked, one on top of the other on a substrate. The package may include interconnections to provide power to the semiconductor dies within the package, as well as to enable transfer of data to and from the dies. Without the stacking of dies, data interconnections between active dies (i.e., in different packages) typically require long interlinks through conductive layers of a package substrate or a circuit board, such as a motherboard. These long interconnect distances increase inductance and may reduce signal performance. However, stacking of dies may increase the overall z-height of a package and may increase thermal and/or mechanical stress on bottom dies. Various ones of the embodiments disclosed herein may help achieve reliable attachment of multiple IC dies at a lower cost, with improved power efficiency, with higher bandwidth, and/or with greater design flexibility, relative to conventional approaches. Further, various ones of the microelectronic assemblies disclosed herein may exhibit better power delivery and signal speed while reducing the size of the package relative to conventional approaches, such as stacked dies. The microelectronic assemblies disclosed herein may be particularly advantageous for small and low-profile, compute-intensive applications in computers, tablets, industrial robots, and consumer electronics (e.g., wearable devices).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified.

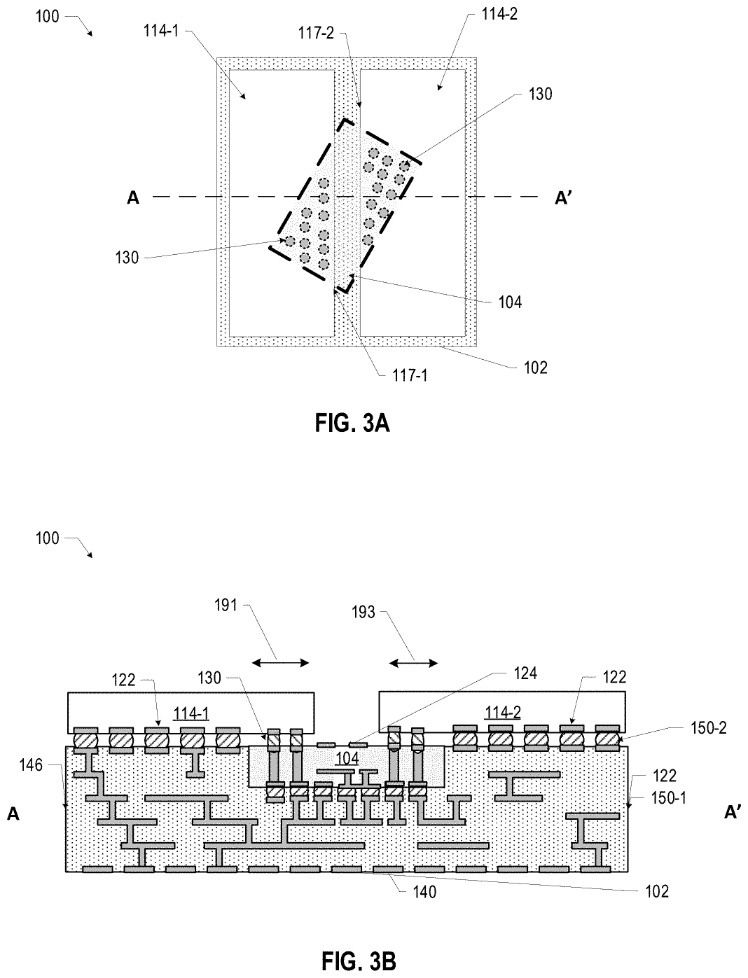

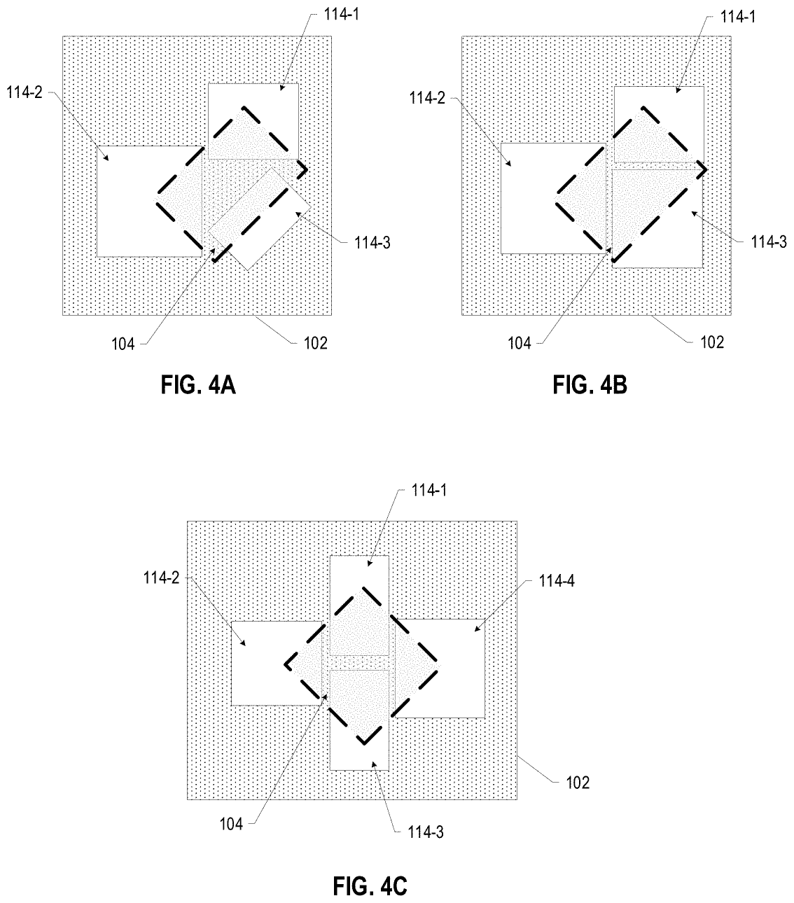

When used to describe a range of dimensions, the phrase “between X and Y” represents a range that includes X and Y. For convenience, the phrase “FIG. 3” may be used to refer to the collection of drawings of FIGS. 3A-3B, the phrase “FIG. 4” may be used to refer to the collection of drawings of FIGS. 4A-4C, etc. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

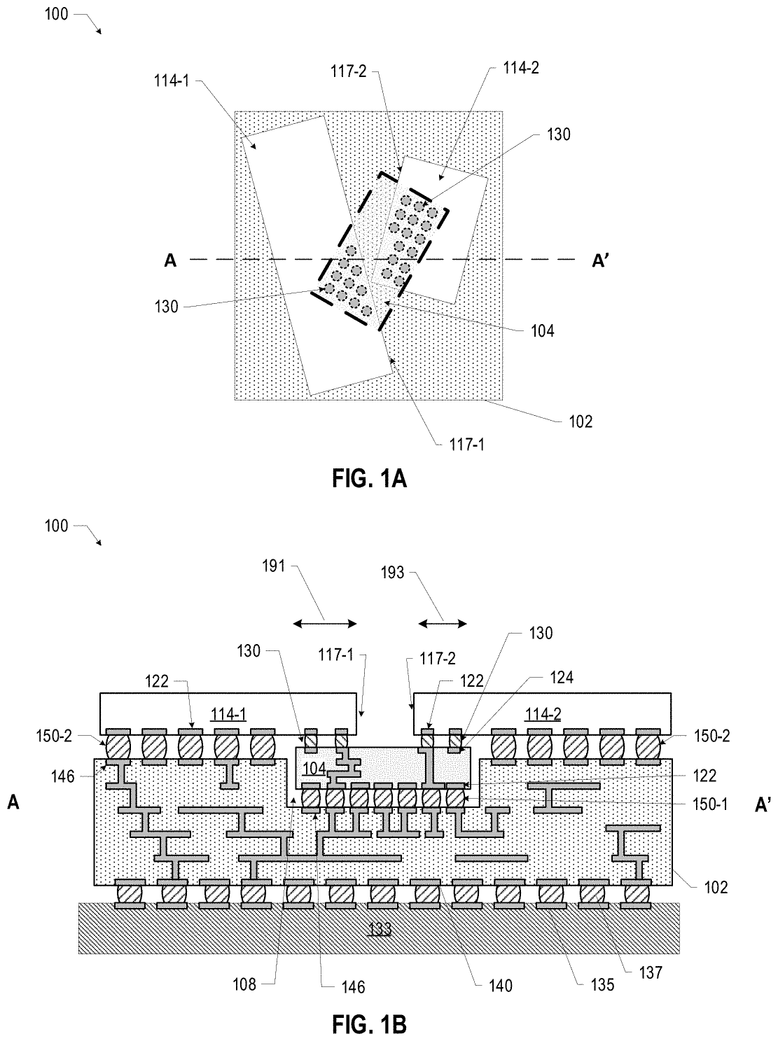

FIG. 1A is a top view of a microelectronic assembly 100, in accordance with various embodiments. The microelectronic assembly 100 may include a package substrate 102, a bridge structure 104, and a first die 114-1 and a second die 114-2, where the first and second dies 114-1, 114-2 are non-rectilinear to the bridge structure 104. In particular, the bridge structure 104 may include a first surface and an opposing second surface having the first surface of the bridge structure 104 coupled to the package substrate 102, and the second surface of the bridge structure 104 coupled to the first die 114-1 and the second die 114-2, such that the bridge structure 104 is between a surface of the package substrate 102 and the first and second dies 114-1, 114-2, and the bridge structure 104 is non-rectilinear to the first and second dies 114-1, 114-2. As used herein, non-rectilinear refers to a component not following or not forming a straight line as compared to another component. In one example, a first component is non-rectilinear to a second component when a connection side of the first component does not follow or form a straight line with a connection side of the second component. As used herein, a connection side is an edge or side of a first component that overlaps a second component, and the overlap defines an area (e.g., an overlap area) where the first component may be coupled to the second component. A component may have more than one connection side (e.g., may overlap on a corner portion of the component). In another example, a first component is non-rectilinear to a second component when an area of overlap between the first and second components is non-rectangular or when an axis of the first component is rotated with respect to an axis of the second component. In another example, a first component is non-rectilinear to a second component when the first component is non-rectangular (e.g., a die 114 having a rectangular shape is non-rectilinear to a bridge structure 104 having a triangular shape). A component may refer to a bridge structure 104 or may refer to a die 114 coupled to the bridge structure 104. For example, as shown in FIG. 1A, the die 114-1 is non-rectilinear to the bridge structure 104 as a connection side 117-1 (e.g., a portion of the perimeter that overlaps the bridge structure) of the die 114-1 does not follow (e.g., is not parallel) to a side of the bridge structure 104 as depicted by the dotted line. In the same manner, the die 114-2 is non-rectilinear to the bridge structure 104 as a connection side 117-2 of the die 114-2 does not follow (e.g., is not parallel) to a side of the bridge structure 104 as depicted by the dotted line. In another example, as shown in FIG. 1A, the die 114-1 is non-rectilinear to the die 114-2 as a connection side 117-1 of the die 114-1 is not parallel to a connection side 117-2 of the die 114-2. In some embodiments, the dies 114-1, 114-2 may be coupled to the bridge structure 104 in a non-rectilinear arrangement to reduce hot spots and improve thermal dispersion. For example, as shown in FIG. 1A, the die 114-1 and the die 114-2 may be spaced apart when coupled to the bridge structure 104, such that heat may dissipate more readily from the dies 114-1, 114-2 and from the bridge structure 104.

As shown in FIG. 1A and described in more detail in reference to FIG. 1B, the first die 114-1 and the second die 114-2 may be coupled to the second surface of the bridge structure 104 by die-to-bridge (DTB) interconnects 130. Although FIG. 1A illustrates the DTB interconnects 130 as being arranged in a rectangular array, this need not be the case, and the DTB interconnects 130 may be arranged in any suitable pattern (e.g., hexagonal, rectangular, etc.).

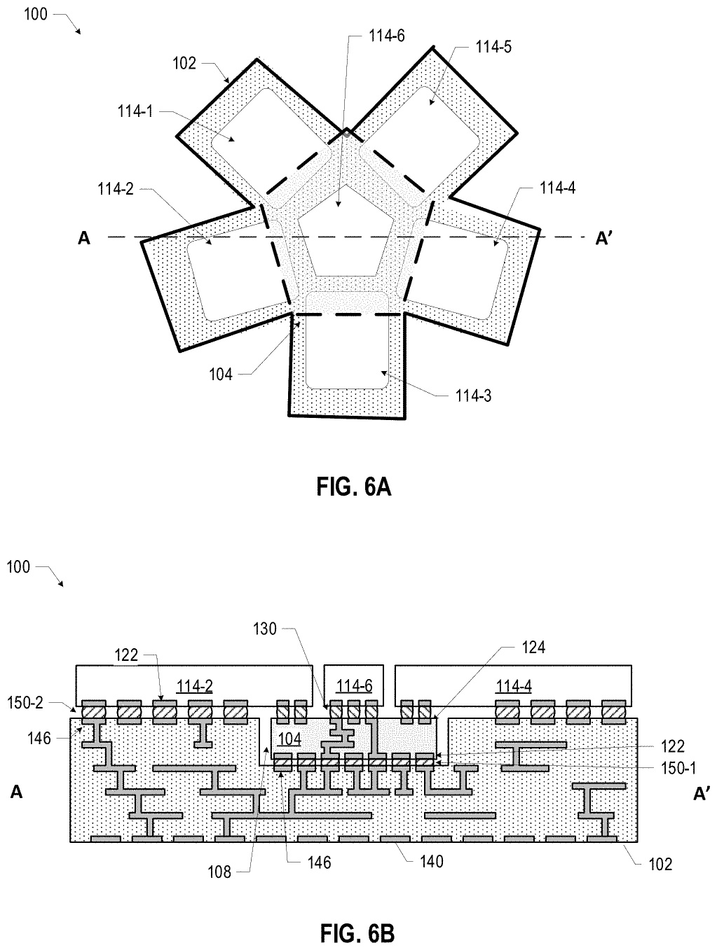

Although FIG. 1A illustrates a particular size, shape, and number of dies 114 (e.g., two dies) coupled to the bridge structure 104, the dies 114 may have any suitable size and shape, including non-rectangular, and any number of dies 114 may be coupled to the bridge structure 104, including one die, two dies, or more than two dies. In some embodiments, the dies 114 may include chamfered or rounded edges. Although FIG. 1A illustrates the bridge structure 104 as having a particular size and shape (e.g., rectangular), the bridge structure 104 may have any suitable size and shape, including a triangle, rectangle, a hexagon, a heptagon, an octagon, a trapezoid, and a rhombus, among others. The bridge structure 104 may be designed to optimize the number of DTB interconnects 130 between the dies 114 and the bridge structure 104, and to minimize the overlap area and/or the size of the bridge structure 104. In some embodiments, the bridge structure 104 may be designed to minimize the distance of connections between the dies 114 and the bridge structure 104, and between a first die and a second die through the bridge structure 104. In some embodiments, the bridge structure 104 may be designed such that a distance of a first conductive pathway between a first die and the bridge structure is equal to a distance of a second conductive pathway between a second die and the bridge structure 104. In some embodiments, the bridge structure 104 may be designed to minimize the signal fan-out from a first die 114-1 as well as the signal fan-in from a second die 114-2, such that the overall power and data signal latency between the dies may be reduced. Although FIG. 1A illustrates the package substrate 102 as having a particular size and shape (e.g. rectangular) the package substrate 102 may have any suitable size and shape, and may take the shape of the bridge structure 104 and attached dies 114, as shown below in FIG. 6.

FIG. 1B is a side, cross-sectional view along the A-A′ line of the microelectronic assembly 100 of FIG. 1A, in accordance with various embodiments. A number of elements are illustrated in FIG. 1B as included in the microelectronic assembly 100, but a number of these elements may not be present in a microelectronic assembly 100. For example, in various embodiments, the second-level interconnects 137, and/or the circuit board 133 may not be included. Further, FIG. 1B illustrates a number of elements that are omitted from subsequent drawings for ease of illustration, but may be included in any of the microelectronic assemblies 100 disclosed herein. Examples of such elements include the second-level interconnects 137, and/or the circuit board 133. Many of the elements of the microelectronic assembly 100 of FIG. 1B are included in other ones of the accompanying figures; the discussion of these elements is not repeated when discussing these figures, and any of these elements may take any of the forms disclosed herein. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

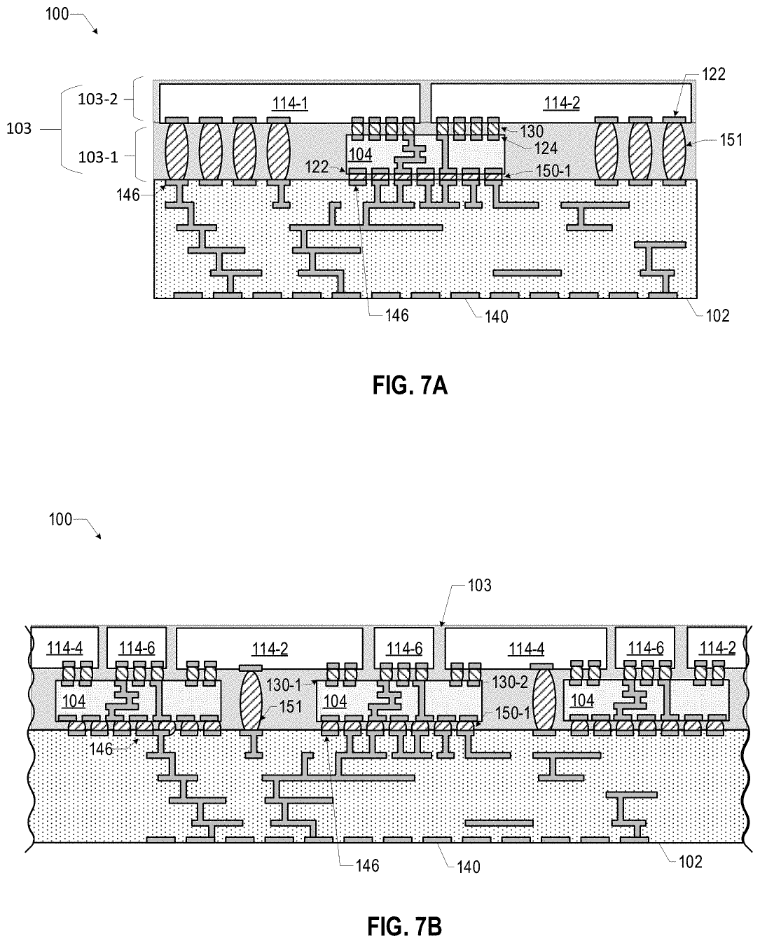

The microelectronic assembly 100 may include a package substrate 102 coupled to a bridge structure 104 by PS interconnects 150-1. In particular, the top surface of the package substrate 102 may include a set of conductive contacts 146, and the bottom surface of the bridge structure 104 may include a set of conductive contacts 122; the conductive contacts 122 at the bottom surface of the bridge structure 104 may be electrically and mechanically coupled to the conductive contacts 146 at the top surface of the package substrate 102 by the PS interconnects 150-1. In the embodiment of FIG. 1B, the top surface of the package substrate 102 includes a recess 108 in which the bridge structure 104 is at least partially disposed; the conductive contacts 146 to which the bridge structure 104 is coupled are located at the bottom of the recess 108. In other embodiments, the bridge structure 104 may not be disposed in a recess (e.g., as discussed below with reference to FIG. 7). Any of the conductive contacts disclosed herein (e.g., the conductive contacts 122, 124, 140, and/or 146) may include bond pads, posts, or any other suitable conductive contact, for example. A die 114 that has package substrate (PS) interconnects 150 and DTB interconnects 130 at the same surface may be referred to as a mixed-pitch die 114; more generally, a die 114 that has DTB interconnects 130 of different pitches at a same surface may be referred to as a mixed-pitch die 114.

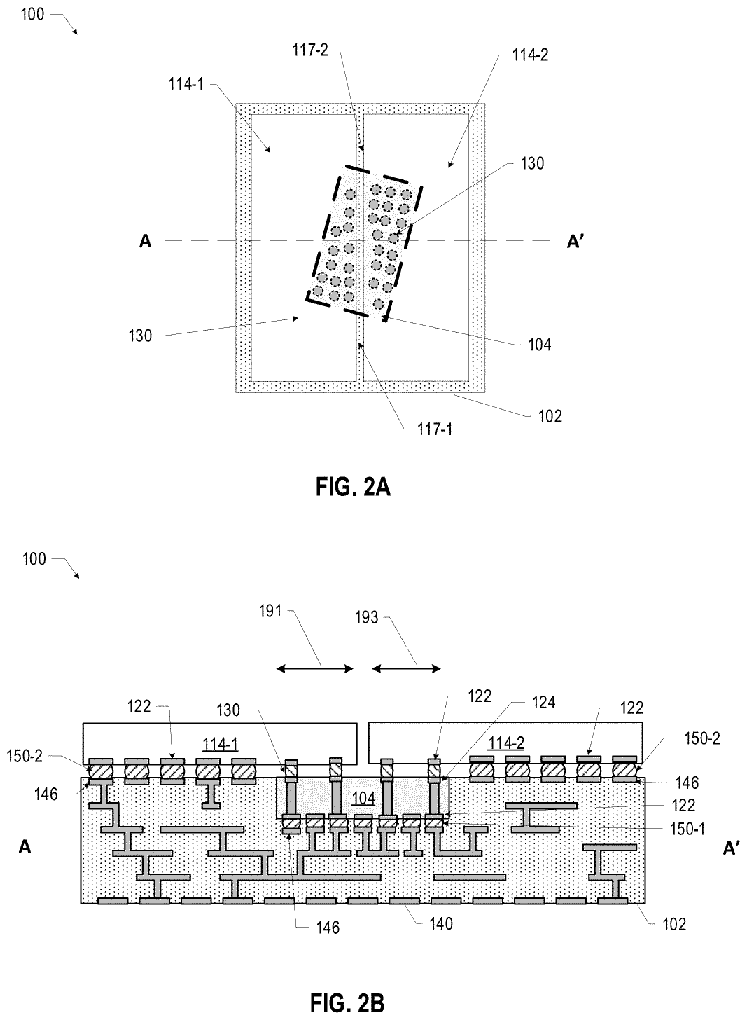

The bridge structure 104 may be a double-sided structure (in the sense that the bridge structure 104 has conductive contacts 122, 124 on two surfaces (e.g., a top surface and a bottom surface)). A bridge structure 104 that has interconnects of different pitches at a same surface (e.g., top surface DTB interconnects 130 or bottom surface interconnects 150-1) or at different surfaces (e.g., top surface DTB interconnects 130 and bottom surface interconnects 150-1) may be referred to as a mixed-pitch structure. In some embodiments, as shown in FIG. 1B, the bridge structure 104 may be a double-sided die. In this context, a double-sided die refers to a die that has connections on both surfaces. In some embodiments, a double-sided die may include through silicon vias (TSVs) to form connections on both surfaces. In some embodiments, a double-sided die may include one or more device layers including transistors (e.g., as discussed below with reference to FIG. 9). When the die includes active circuitry, power and/or ground signals may be routed through the package substrate 102 and to the die through the conductive contacts 122 on the bottom surface of the die. The active surface of a double-sided die, which is the surface containing one or more active devices and a majority of interconnects, may face either direction depending on the design and electrical requirements. In some embodiments, as shown below in FIG. 2B, the bridge structure 104 may be a passive interposer and may only include conductive pathways (e.g., TSVs), and may not contain active or passive circuitry. In some embodiments, the bridge structure 104 may be a passive interposer having active and/or passive circuitry and TSVs. In some embodiments, as shown below in FIG. 3B, the bridge structure 104 may be an active interposer and may include active or passive circuitry (e.g., transistors, diodes, resistors, inductors, and capacitors, among others).

The microelectronic assembly 100 of FIG. 1B may also include the dies 114-1, 114-2. The dies 114-1, 114-2 may be electrically and mechanically coupled to the bridge structure 104 in a non-rectilinear arrangement by DTB interconnects 130. In some embodiments, the dies 114-1, 114-2 may be electrically and mechanically coupled to the package substrate 102 by PS interconnects 150-2. In particular, the top surface of the package substrate 102 may include a set of conductive contacts 146, and the bottom surface of the dies 114-1, 114-2 may include a set of conductive contacts 122; the conductive contacts 122 at the bottom surface of the dies 114-1, 114-2 may be electrically and mechanically coupled to the conductive contacts 146 at the top surface of the package substrate 102 by the PS interconnects 150-2. Further, the top surface of the bridge structure 104 may include a set of conductive contacts 124, and the bottom surface of the dies 114-1, 114-2 may include a set of conductive contacts 122; the conductive contacts 122 at the bottom surface of the dies 114-1, 114-2 may be electrically and mechanically coupled to some of the conductive contacts 124 at the top surface of the bridge structure 104 by the DTB interconnects 130. In some embodiments, the top surface of the bridge structure 104 may extend higher than the top surface of the package substrate 102, as illustrated in FIG. 1B. In other embodiments, the top surface of the bridge structure 104 may be substantially coplanar with the top surface of the package substrate 102, or may be recessed below the top surface of the package substrate 102. Although various ones of the figures illustrate microelectronic assemblies 100 having a single recess 108 in the package substrate 102, the thickness of 102 may include multiple recesses 108 (e.g., having the same or different dimensions, and each having a die 114 disposed therein), or no recesses, as shown in FIG. 7.

Although FIG. 1B shows the dies 114-1, 114-2 as single-sided dies, the dies 114-1, 114-2 may be single-sided or double-sided dies and may be a single-pitch die or a mixed-pitch die. In some embodiments, additional components may be disposed on the top surface of the dies 114-1, 114-2. Additional passive components, such as surface-mount resistors, capacitors, and/or inductors, may be disposed on the top surface or the bottom surface of the package substrate 102, or embedded in the package substrate 102. As shown in FIG. 1B, the PS interconnects 150-1 of the bridge structure 104 may have a different pitch from the PS interconnects 150-2 of the dies 114-1, 114-2. In some embodiments, the PS interconnects 150 of the die 114-1 may be different than the PS interconnects 150 of the die 114-2. In some embodiments, the PS interconnects 150 may have a different pitch on the same die. In another example, the DTB interconnects 130 may have a different pitch on the same surface. In some embodiments, the DTB interconnects may have a pitch between 5 microns and 200 microns (e.g., between 7 microns and 100 microns). In some embodiments, the PS interconnects may have a pitch between 30 microns and 800 microns (e.g., between 80 microns and 300 microns, or between 300 microns and 600 microns).

In the embodiment of FIG. 1, the dies 114-1, 114-2 are illustrated as “spanning” the package substrate 102 and the bridge structure 104. For example, FIG. 1B illustrates an embodiment in which dies 114-1, 114-2, each have conductive contacts 122 disposed at the bottom surfaces; some of the conductive contacts 122 of the dies 114-1, 114-2 may be coupled to conductive contacts 146 at the top surface of the package substrate 102 via PS interconnects 150-2, and some of the conductive contacts 122 of the dies 114-1, 114-2 may be coupled to conductive contacts 124 at the top surface of the bridge structure 104 via DTB interconnects 130. The die 114-1 may extend over the bridge structure by an overlap distance 191. As used herein, the overlap distance 191 refers to a distance between a connection side 117-1 of a die 114-1 and a side of the bridge structure 104 that is overlapped. The die 114-2 may extend over the bridge structure 104 by an overlap distance 193. As used herein, the overlap distance 193 refers to a distance between a connection side 117-2 of a die 114-2 and a side of the bridge structure 104 that is overlapped. As the dies 114-1, 114-2 are arranged non-rectilinear to the bridge structure 104, the overlap distances 191, 193 may vary along a horizontal plane (e.g., cross-sectional line position). In some embodiments, the overlap distances 191, 193 may be equal or the same. In some embodiments, the overlap distances 191, 193 may be different. In some embodiments, the overlap distances 191, 193 may be between 0.5 millimeters and 20 millimeters (e.g., between 3 millimeters and 15 millimeters, or approximately 5 millimeters). In some embodiments, power and/or ground signals may be provided directly to the bridge structure 104 and the dies 114-1, 114-2 of the microelectronic assembly 100 of FIG. 1B through the package substrate 102, and the bridge structure 104 may, among other things, route signals between the dies 114-1, 114-2.

In some embodiments, the dies 114 in any of the microelectronic assemblies 100 disclosed herein may include on-package memory devices (e.g., random access memory (RAM)), I/O circuitry (e.g., I/O drivers), high bandwidth memory, accelerators, application-specific integrated circuits (e.g., artificial intelligence application-specific integrated circuits), a field programmable gate array, or any other suitable circuitry. In some embodiments, the microelectronic assembly 100 may be included in a server, and the dies 114 may be processing cores. In some such embodiments, it may be useful to have memory devices physically proximate to these processing cores, and thus some of the dies may be memory devices.

In some embodiments, the package substrate 102 may be a lower density medium and the bridge structure 104 and the dies 114-1, 114-2 may be a higher density medium. As used herein, the term “lower density” and “higher density” are relative terms indicating that the conductive pathways (e.g., including conductive lines and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a printed circuit board (PCB) manufactured using a standard PCB process (e.g., a standard subtractive process using etch chemistry to remove areas of unwanted copper, and with coarse vertical interconnect features formed by a standard laser process). In some embodiments, the package substrate 102 may be a set of redistribution layers formed on a wafer or panel carrier by laminating or spinning on a dielectric material, and creating conductive vias and lines by laser drilling or lithography and plating. Any suitable technique may be used to form the recess 108. For example, in some embodiments, the recess 108 may be laser-drilled down to a planar metal stop in the package substrate 102; once the metal stop is reached, the metal stop may be removed to expose the conductive contacts 146 at the bottom of the recess 108. In some embodiments, the recess 108 may be formed by a mechanical drill. Any method known in the art for fabrication of the package substrate 102 may be used, and for the sake of brevity, such methods will not be discussed in further detail herein.

The package substrate 102 may include an insulating material (e.g., a dielectric material formed in multiple layers, as known in the art) and one or more conductive pathways through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), bismaleimide triazine (BT) resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable.

In some embodiments, one or more of the conductive pathways in the package substrate 102 may extend between a conductive contact 146 at the top surface of the package substrate 102 and a conductive contact 140 at the bottom surface of the package substrate 102. In some embodiments, one or more of the conductive pathways in the package substrate 102 may extend between a conductive contact 146 at the bottom of the recess 108 and a conductive contact 140 at the bottom surface of the package substrate 102. In some embodiments, one or more of the conductive pathways in the package substrate 102 may extend between different conductive contacts 146 at the top surface of the package substrate 102 (e.g., between a conductive contact 146 at the bottom of the recess 108 and a different conductive contact 146 at the top surface of the package substrate 102). In some embodiments, one or more of the conductive pathways in the package substrate 102 may extend between different conductive contacts 140 at the bottom surface of the package substrate 102.

The dies 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 9. The conductive pathways in the dies 114 may be bordered by liner materials, such as adhesion liners and/or barrier liners, as suitable.

Although FIG. 1B illustrates a specific number and arrangement of conductive pathways in the package of 102 and/or the bridge structure 104, these are simply illustrative, and any suitable number and arrangement may be used. The conductive pathways disclosed herein (e.g., conductive traces and/or conductive vias) may be formed of any appropriate conductive material, such as copper, silver, nickel, gold, aluminum, or other metals or alloys, for example.

As discussed above, in the embodiment of FIG. 1, the bridge structure 104 may provide high density interconnect routing in a localized area of the microelectronic assembly 100. In some embodiments, the bridge structure 104 may support direct chip attach of semiconductor dies including a fine-pitch (e.g., the dies 114-1 and 114-2) that cannot be attached entirely directly to the package substrate 102. The proliferation of wearable and mobile electronics, as well as Internet of Things (IoT) applications, are driving reductions in the size of electronic systems, but limitations of the PCB manufacturing process and the mechanical consequences of thermal expansion during use have meant that chips having fine interconnect pitch cannot be directly mounted to a PCB. Various embodiments of the microelectronic assemblies 100 disclosed herein may be capable of supporting chips with high density interconnects and chips with low-density interconnects without sacrificing performance or manufacturability.

The microelectronic assembly 100 of FIG. 1B may also include a circuit board 133. The package substrate 102 may be coupled to the circuit board 133 by second-level interconnects 137 at the bottom surface of the package substrate 102. In particular, the package substrate 102 may include conductive contacts 140 at its bottom surface, and the circuit board 133 may include conductive contacts 135 at its top surface; the second-level interconnects 137 may electrically and mechanically couple the conductive contacts 135 and the conductive contacts 140. The second-level interconnects 137 illustrated in FIG. 1B are solder balls (e.g., for a ball grid array arrangement), but any suitable second-level interconnects 137 may be used (e.g., pins in a pin grid array arrangement or lands in a land grid array arrangement). The circuit board 133 may be a motherboard, for example, and may have other components attached to it (not shown). The circuit board 133 may include conductive pathways and other conductive contacts (not shown) for routing power, ground, and signals through the circuit board 133, as known in the art. In some embodiments, the second-level interconnects 137 may not couple the package substrate 102 to a circuit board 133, but may instead couple the package substrate 102 to another IC package, an interposer, or any other suitable component.

The microelectronic assembly 100 of FIG. 1B may also include a mold material (not shown). The mold material may extend around one or more of the dies 114 on the package substrate 102. In some embodiments, the mold material may extend above one or more of the dies 114 on the package substrate 102. In some embodiments, the mold material may extend between one or more of the dies 114 and the package substrate 102 around the associated PS interconnects 150; in such embodiments, the mold material may serve as an underfill material. In some embodiments, the mold material may extend between different ones of the dies 114 around the associated DTB interconnects 130; in such embodiments, the mold material may serve as an underfill material. The mold material may include multiple different mold materials (e.g., an underfill material, and a different overmold material). The mold material may be an insulating material, such as an appropriate epoxy material. In some embodiments, the mold material may include an underfill material that is an epoxy flux that assists with soldering the bridge structure 104 and the dies 114-1, 114-2 to the package substrate 102 when forming the PS interconnects 150-1 and 150-2, respectively, and then polymerizes and encapsulates the PS interconnects 150-1 and 150-2. The mold material may be selected to have a coefficient of thermal expansion (CTE) that may mitigate or minimize the stress between the bridge structure 104, the dies 114, and the package substrate 102 arising from uneven thermal expansion in the microelectronic assembly 100. In some embodiments, the CTE of the mold material may have a value that is intermediate to the CTE of the package substrate 102 (e.g., the CTE of the dielectric material of the package substrate 102) and a CTE of the bridge structure 104 and/or the dies 114.

The microelectronic assembly 100 of FIG. 1B may also include a thermal interface material (TIM) (not shown). The TIM may include a thermally conductive material (e.g., metal particles) in a polymer or other binder. The TIM may be a thermal interface material paste or a thermally conductive epoxy (which may be a fluid when applied and may harden upon curing, as known in the art). The TIM may be a solder TIM (e.g. indium or indium silver alloy, among others). The TIM may provide a path for heat generated by the dies 114 to readily move away from the dies and/or to a heat spreader, where it may be spread and/or dissipated. Some embodiments of the microelectronic assembly 100 of FIG. 1B may include a sputtered back side metallization (not shown) across the mold material and the dies 114; the TIM (e.g., a solder TIM) may be disposed on this back side metallization.

The microelectronic assembly 100 of FIG. 1B may also include a heat spreader (not shown). The heat spreader may be used to move heat away from the dies 114 (e.g., so that the heat may be more readily dissipated by a heat sink or other thermal management device). The heat spreader may include any suitable thermally conductive material (e.g., metal, appropriate ceramics, etc.), and may include any suitable features (e.g., fins). In some embodiments, the heat spreader may be an integrated heat spreader.

The PS interconnects 150 disclosed herein may take any suitable form. In some embodiments, a set of PS interconnects 150 may include solder (e.g., solder bumps or balls that are subject to a thermal reflow to form the PS interconnects 150). PS interconnects 150 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of PS interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTB interconnects 130 disclosed herein may take any suitable form. The DTB interconnects 130 may have a finer pitch than the PS interconnects 150 in a microelectronic assembly. In some embodiments, the dies 114 on either side of a set of DTB interconnects 130 may be unpackaged dies, and/or the DTB interconnects 130 may include small conductive bumps or pillars (e.g., copper bumps or pillars) attached to the conductive contacts by solder. In some embodiments, a set of DTB interconnects 130 may include solder. DTB interconnects 130 that include solder may include any appropriate solder material, such as any of the materials discussed above. In some embodiments, a set of DTB interconnects 130 may include an anisotropic conductive material, such as any of the materials discussed above. In some embodiments, the DTB interconnects 130 may be used as data transfer lanes, while the PS interconnects 150 may be used for power and ground lines, among others. In some embodiments, some or all of the DTB interconnects 130 in a microelectronic assembly 100 may be metal-to-metal interconnects (e.g., copper-to-copper interconnects, or plated interconnects). In some embodiments, some or all of the DTB interconnects 130 in a microelectronic assembly 100 may be solder interconnects that include a solder with a higher melting point than a solder included in some or all of the PS interconnects 150. For example, when the DTB interconnects 130 in a microelectronic assembly 100 are formed before the PS interconnects 150 are formed (e.g., when the dies 114-1, 114-2 are coupled to the bridge structure and form a subassembly that is coupled to the package substrate 102), solder-based DTB interconnects 130 may use a higher-temperature solder (e.g., with a melting point above 200 degrees Celsius), while the PS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

Any suitable technique may be used to form the DTB interconnects 130 and attach the dies 114 to the bridge structure 104, such as metal-to-metal attachment techniques, solder techniques, or anisotropic conductive material techniques. In some embodiments, the dies 114 may be coupled to the top surface of the bridge structure 104 via the DTB interconnects 130, and then the bridge structure 104 and the attached dies 114 may be coupled to the top surface of the package substrate 102 via the PS interconnects 150. In some embodiments, the bridge structure 104 may be coupled to the package substrate via PS interconnects 150, and then the dies 114 may be coupled to the bridge structure 104 via DTB interconnects 130 and to the package substrate 102 via PS interconnects 150. The PS interconnects 150 and DTB interconnects 130 may take any of the forms disclosed herein (e.g., solder interconnects, or anisotropic conductive material interconnects), and any suitable techniques may be used to form the PS interconnects 150 and DTB interconnects 130 (e.g., a mass reflow process or a thermal compression bonding process).

FIG. 2A is a top view of a microelectronic assembly 100, in accordance with various embodiments. The microelectronic assembly 100 may include a package substrate 102, a bridge structure 104, and a first die 114-1 and a second die 114-2, where the first and second dies 114-1, 114-2 are non-rectilinear to the bridge structure 104. In particular, the bridge structure 104 may include a first surface and an opposing second surface having the first surface of the bridge structure 104 coupled to the package substrate 102, and the second surface of the bridge structure 104 coupled to the first die 114-1 and the second die 114-2, such that the bridge structure 104 is between a surface of the package substrate 102 and the first and second dies 114-1, 114-2. As shown in FIG. 2A, the bridge structure 104 is non-rectilinear to the first and second dies 114-1, 114-2, and the first and second dies 114-1, 114-2 are rectilinear to each other. The die 114-1 is non-rectilinear to the bridge structure 104 as a connection side 117-1 of the die 114-1 is not parallel to a side of the bridge structure 104 as depicted by the dotted line. In the same manner, the die 114-2 is non-rectilinear to the bridge structure 104 as a connection side 117-2 of the die 114-2 is not parallel to a side of the bridge structure 104 as depicted by the dotted line. In some embodiments, the dies 114-1, 114-2 may be coupled to the bridge structure 104 in a non-rectilinear arrangement to increase the overlap area of the dies 114-1, 114-2 and the bridge structure 104, and to optimize the number and arrangement of DTB interconnects 130. For example, as shown in FIG. 2A, the die 114-1 and the die 114-2 may be spaced closely together when coupled to the bridge structure 104, such that the overlap area may be maximized and the arrangement of DTB interconnects 130 may be maximized.

FIG. 2B is a side, cross-sectional view along the A-A′ line of the microelectronic assembly 100 of FIG. 2A, in accordance with various embodiments. In some embodiments, as shown in FIG. 2B, the dies 114-1, 114-2 may be coupled to the bridge structure 104 in a non-rectilinear arrangement that optimizes the overlap distances 191, 193, and places the dies 114-1, 114-2 close together, such that the dies 114-1, 114-2 span the bridge structure 104. FIG. 2B illustrates the bridge structure 104 as a passive interposer having TSVs that connect the dies 114-1, 114-2 to the package substrate 102 via interconnects 150-1, 150-2.

FIG. 3A is a top view of a microelectronic assembly 100, in accordance with various embodiments. The microelectronic assembly 100 may include a package substrate 102, a bridge structure 104, and a first die 114-1 and a second die 114-2, where the first and second dies 114-1, 114-2 are non-rectilinear to the bridge structure 104. In particular, the bridge structure 104 may include a first surface and an opposing second surface having the first surface of the bridge structure 104 coupled to the package substrate 102, and the second surface of the bridge structure 104 coupled to the first die 114-1 and the second die 114-2, such that the bridge structure 104 is between a surface of the package substrate 102 and the first and second dies 114-1, 114-2. As shown in FIG. 3A, the bridge structure 104 is non-rectilinear to the first and second dies 114-1, 114-2, and the first and second dies 114-1, 114-2 are rectilinear to each other. The die 114-1 is non-rectilinear to the bridge structure 104 as a connection side 117-1 of the die 114-1 is not parallel to a side of the bridge structure 104 as depicted by the dotted line. In the same manner, the die 114-2 is non-rectilinear to the bridge structure 104 as a connection side 117-2 of the die 114-2 is not parallel to a side of the bridge structure 104 as depicted by the dotted line. In some embodiments, the dies 114-1, 114-2 may be coupled to the bridge structure 104 in a non-rectilinear arrangement and may be spaced apart, as described above with reference to FIG. 1. For example, as shown in FIG. 3A, the die 114-1 and the die 114-2 may be spaced apart when coupled to the bridge structure 104. By placing the die 114-1 apart from the die 114-2, heat may dissipate more readily from the dies 114-1, 114-2 and from the bridge structure 104 to reduce hot spots and improve thermal dispersion and/or thermal dissipation.

FIG. 3B is a side, cross-sectional view along the A-A′ line of the microelectronic assembly 100 of FIG. 3A, in accordance with various embodiments. In some embodiments, as shown in FIG. 3B, the dies 114-1, 114-2 may be coupled to the bridge structure 104 in a non-rectilinear arrangement that reduces the overlap distances 191, 193, and places the dies 114-1, 114-2 apart from each other. FIG. 3B illustrates the bridge structure 104 as an active interposer having active circuitry and TSVs that connect the dies 114-1, 114-2 to the package substrate 102 via interconnects 150-1, 150-2.

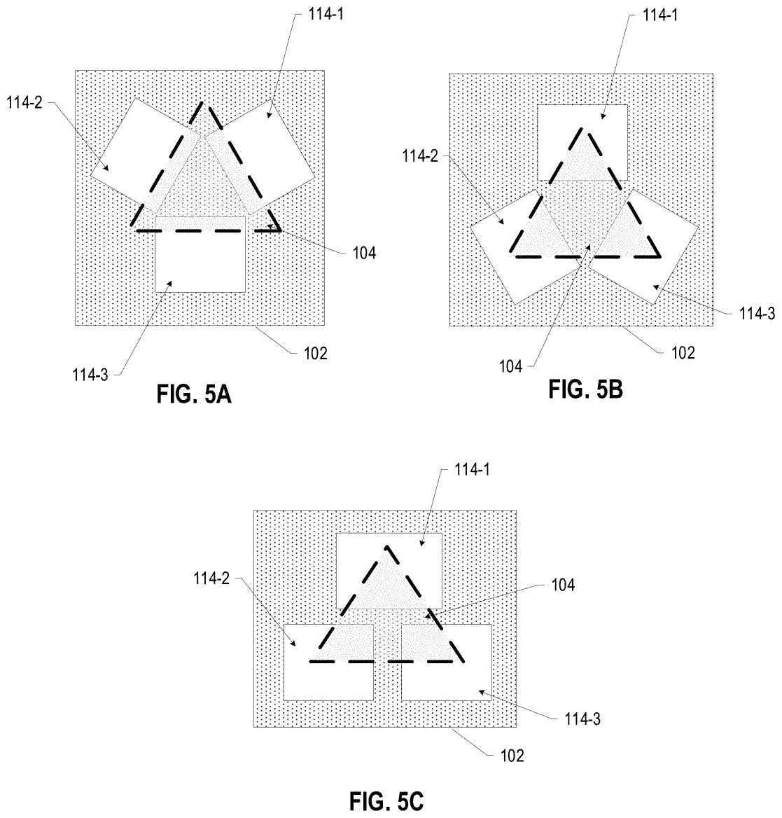

FIGS. 4-5 are top views of example arrangements of multiple dies 114 in various microelectronic assemblies 100, in accordance with various embodiments. The DTB interconnects 130 are omitted from FIGS. 4-5; some or all of the bridge structure 104 in these arrangements may be at least partially disposed in a recess 108 in a package substrate 102, or may not be disposed in a recess of a package substrate 102. In the arrangements of FIGS. 4-5, the bridge structure 104 may include any suitable circuitry as described above with reference to FIG. 1. Although dies 114 having rectangular footprints are illustrated herein, the dies 114 may have any desired footprints (e.g., triangular, hexagonal, etc.), and such dies 114 may be arranged in any desired array (e.g., triangular, hexagonal, etc.).

FIG. 4A illustrates an arrangement in which a bridge structure 104 is disposed below multiple different dies 114-1, 114-2, 114-3. The dies 114 may be coupled to the bridge structure 104 in a non-rectilinear arrangement where the dies 114-1, 114-2 are non-rectilinear to the bridge structure (e.g., the dies 114-1, 114-2 overlap the corners of the bridge structure 104), and the die 114-3 is non-rectilinear to the dies 114-1, 114-2. The dies 114 may be coupled to the bridge structure in any manner disclosed herein.

FIG. 4B illustrates an arrangement in which a bridge structure 104 is disposed below multiple different dies 114-1, 114-2, 114-3. The dies 114 may be coupled to the bridge structure 104 in a non-rectilinear arrangement where the dies 114-1, 114-2, 114-3 are non-rectilinear to the bridge structure (e.g., the dies 114-1, 114-2 overlap the corners of the bridge structure 104 and the bridge structure overlaps a corner of the die 114-3), and the dies 114-1, 114-2, 114-3 are rectilinear to each other. The close arrangement of the dies 114 to each other and the size of the bridge structure 104 provides for an optimized (e.g., greater) overlap area (e.g., connection area for DTB interconnects) for the dies 114 as compared to FIG. 4A. As shown in FIG. 4B, the overlap area between the bridge structure 104 and an individual die 114-1, 114-2, 114-3 is non-rectilinear as the overlap areas are non-rectangular.

FIG. 4C illustrates an arrangement in which a bridge structure 104 is disposed below multiple different dies 114-1, 114-2, 114-3, 114-4. The dies 114 may be coupled to the bridge structure 104 in a non-rectilinear arrangement where the dies 114 are non-rectilinear to the bridge structure (e.g., the dies 114-1, 114-2, 114-3, 114-4 overlap the corners of the bridge structure 104), and the dies 114-1, 114-2, 114-3, 114-4 are rectilinear to each other. As shown in FIG. 4C, the dies 114 may have different sizes and shapes to optimize the overlap area for DTB interconnections between the bridge structure 104 and the dies 114.

FIG. 5A illustrates an arrangement in which a bridge structure 104 is disposed below multiple different dies 114-1, 114-2, 114-3. As shown in FIG. 5, the bridge structure 104 has a triangular shape and the dies 114 have a rectangular shape. The dies 114 may be coupled to the bridge structure 104 in a non-rectilinear arrangement where the dies 114-1, 114-2, 114-3 are non-rectilinear to the bridge structure (e.g., the dies 114-1, 114-2, 114-3 overlap the edges or sides of the bridge structure 104, which is nonrectangular) and the dies 114-1, 114-2, 114-3 are non-rectilinear to each other.

FIG. 5B illustrates an arrangement in which a bridge structure 104 is disposed below multiple different dies 114-1, 114-2, 114-3. The dies 114 may be coupled to the bridge structure 104 in a non-rectilinear arrangement where the dies 114-1, 114-2, 114-3 are non-rectilinear to the bridge structure (e.g., the dies 114-1, 114-2, 114-3 overlap the corners of the bridge structure 104). In this arrangement, the dies 114-1, 114-2, 114-3 also are non-rectilinear to each other.

FIG. 5C illustrates an arrangement in which a bridge structure 104 is disposed below multiple different dies 114-1, 114-2, 114-3. The dies 114 may be coupled to the bridge structure 104 in a non-rectilinear arrangement where the dies 114-1, 114-2, 114-3 are non-rectilinear to the bridge structure (e.g., the dies 114-1, 114-2, 114-3 overlap the corners of the bridge structure 104). In this arrangement, the dies 114-1, 114-2, 114-3 are rectilinear to each other.

In some embodiments, the bridge structure 104 may be arranged as a bridge between multiple other dies 114, and may also have additional dies 114 disposed thereon (e.g., wholly above the bridge structure). For example, FIGS. 6A and 6B illustrate an embodiment in which five dies 114-1-114-5 are coupled to a bridge structure 104 in a non-rectilinear arrangement, and a sixth die 114-6 is disposed on the bridge structure 104 (e.g., the die 114-6 has a footprint that is wholly within a footprint of the bridge structure 104). The dies 114-1-114-5 each have conductive contacts 122 disposed at the bottom surfaces; the conductive contacts 122 of the dies 114-1-114-5 are coupled to the conductive contacts 124 on the top surface of the bridge structure 104 via DTB interconnects 130 (e.g., as discussed above with reference to FIG. 1). In some embodiments, the conductive contacts 122 disposed at the bottom surfaces of the dies 114-1-114-5 are coupled to conductive contacts 146 at the top surface of the package substrate 102 via PS interconnects 150-2 (e.g., as discussed above with reference to FIG. 1). Additionally, a die 114-6 (or multiple dies 114-6, not shown) is coupled to the bridge structure by DTB interconnects 130 (e.g., as discussed above with reference to FIG. 1). In some embodiments, a die 114-6 may be a die stack (e.g., wafer stacked, die stacked, or multi-layer die stacked). In some embodiments, a die 114-6 may be one of a plurality of dies. FIG. 6A further illustrates a package substrate 102 having a non-rectangular shape, where the shape of the package substrate 102 follows the non-rectilinear arrangement of the dies 114 and the bridge structure 104. Although FIG. 6 illustrates the bridge structure 104, the dies 114, and the package substrate 102 as having particular sizes and shapes, the bridge structure 104, the dies 114, and the package substrate 102 may have any suitable size and shape, as described above with reference to FIG. 1. In some embodiments, a bridge structure 104 may have n-number of sides and n-number of dies attached. In some embodiments, as shown in FIG. 6A, a bridge structure 104 may have n-number of sides and n+1 number of dies coupled, where one die is disposed thereon. In some embodiments. a bridge structure 104 may have n-number of sides and n+2 number of dies attached, where two dies are disposed thereon. In some embodiments, a bridge structure may have n-number of sides and (n+x) number of dies coupled, where x is equal to two or more than the n-number of sides, where the x number of dies are disposed thereon, and where the x-number of dies are stacked (e.g., a stacked die).

FIG. 6B is a side, cross-sectional view along the A-A′ line of the microelectronic assembly 100 of FIG. 6A, in accordance with various embodiments. In some embodiments, as shown in FIG. 6B, the dies 114-2, 114-4 may be coupled to the bridge structure 104 via DTB interconnects 130 in a non-rectilinear arrangement, and the die 114-6 may be disposed on and coupled to the bridge structure 104 via DTB interconnects 130. In some embodiments, two or more dies 114-6 may be disposed on the bridge structure 104 (e.g., wholly above the bridge structure), and may be side-by-side or may be stacked.

As noted above, in some embodiments, the package substrate 102 may not include any recesses 108. For example, FIG. 7A illustrates an embodiment having the dies 114 coupled to a bridge structure 104 in a non-rectilinear arrangement, but in which the bridge structure 104 is not disposed in a recess in the package substrate 102. Instead, the bridge structure 104 and the dies 114-1, 114-2 are disposed above a planar portion of the top surface of the package substrate 102. Any suitable ones of the embodiments disclosed herein that include recesses 108 may have counterpart embodiments that do not include a recess 108. Further, in some embodiments, the bridge structure 104 and the dies 114 may be embedded in dielectric layers 103. As shown in FIG. 7A, the bridge structure 104 may be embedded in a first dielectric layer 103-1 and the dies 114-1, 114-2 may be embedded in a second dielectric layer 103-2. The dies 114-1, 114-2 may be coupled to the bridge structure by DTB interconnects 130, and may be coupled to the package substrate 102 by through dielectric conductive pathways 151, such as conductive vias or conductive pillars. The dielectric layers may be formed using any suitable process, including lamination, or slit coating and curing. The conductive vias or pillars may be formed using any suitable process, including electroplating, sputtering, or electroless plating. In some embodiments, the conductive vias or pillars may be formed by depositing and patterning a photoresist material or a photo-imageable dielectric (PID) to form one or more openings, depositing conductive material in the one or more openings, and removing the photoresist or PID material. The bridge structure 104 may be coupled to the package substrate via PS interconnects 150-1 as described above with reference to FIG. 1. In some embodiments, a microelectronic assembly 100 may include one or more redistribution layers (RDL) (not shown). In some embodiments, an RDL may be included above the second dielectric layer 103-2 (e.g., on the top surface of the dies 114-1, 114-2). In some embodiments, an RDL may be included between the first dielectric layer 103-1 and the second dielectric layer 103-2. In some embodiments, an RDL may be included between the package substrate 102 and the first dielectric layer 103-1.

Any of the non-rectilinear arrangements of dies 114 and bridge structures 104 illustrated in any of the accompanying figures may be part of a continuing arrangement in a microelectronic assembly 100. For example, FIG. 7B illustrates a portion of a microelectronic assembly 100 in which a non-rectilinear arrangement similar the one of FIG. 6 is repeated, with multiple bridge structures 104 and multiple dies 114. In particular, FIG. 7B illustrates a microelectronic assembly 100 having dies 114-2, 114-4 coupled to a package substrate 102 via interconnects 151 in the manner discussed above with reference to FIG. 7A, and dies 114-2, 114-4, 114-6 coupled to the bridge structure 104 via DTB interconnects 130, but in which the bridge structure 104 is not disposed in a recess in the package substrate 102. The dies 114-2, 114-4 may span or overlap the adjacent bridge structures 104, and the die 114-6 may be disposed on the bridge structures 104. More generally, the microelectronic assemblies 100 disclosed herein may include any suitable arrangement of dies 114 and bridge structures 104.

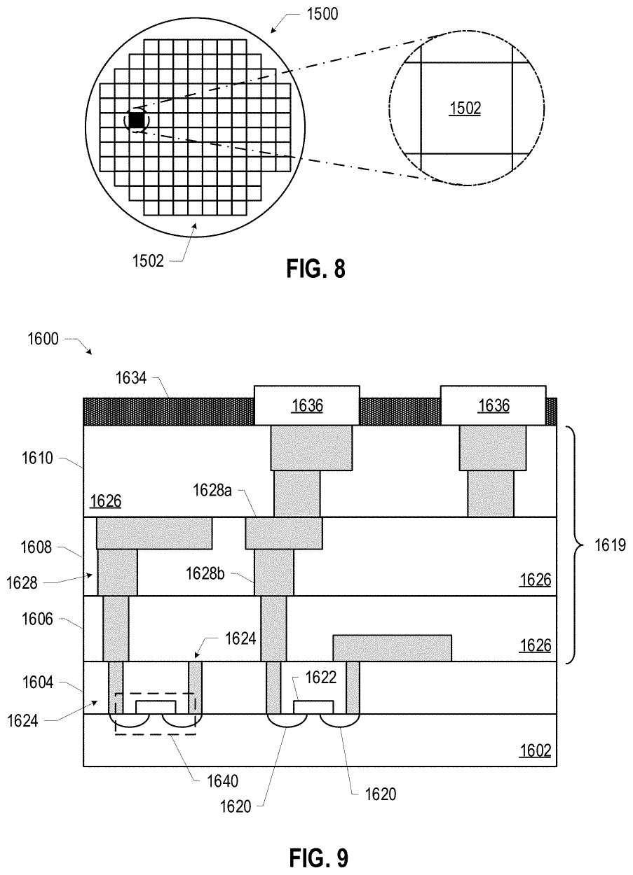

The microelectronic assemblies 100 disclosed herein may be included in any suitable electronic component. FIGS. 8-11 illustrate various examples of apparatuses that may include, or be included in, any of the microelectronic assemblies 100 disclosed herein.

FIG. 8 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 9, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a RAM device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array. In some embodiments, a die 1502 may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 9 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 8). The IC device 1600 may be formed on a die substrate 1602 (e.g., the wafer 1500 of FIG. 8) and may be included in a die (e.g., the die 1502 of FIG. 8). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 8) or a wafer (e.g., the wafer 1500 of FIG. 8).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect pathways 1628 of the interconnect layers 1606-1610. The one or more interconnect layers 1606-1610 may form a metallization stack (also referred to as an “ILD stack”) 1619 of the IC device 1600.

The interconnect pathways 1628 may be arranged within the interconnect layers 1606-1610 to route electrical signals according to a wide variety of designs; in particular, the arrangement is not limited to the particular configuration of interconnect pathways 1628 depicted in FIG. 9. Although a particular number of interconnect layers 1606-1610 is depicted in FIG. 9, embodiments of the present disclosure include IC devices having more or fewer interconnect layers than depicted.

In some embodiments, the interconnect pathways 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 9. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect pathways 1628, as shown in FIG. 9. In some embodiments, the dielectric material 1626 disposed between the interconnect pathways 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 9, the conductive contacts 1636 are illustrated as taking the form of bond pads. The conductive contacts 1636 may be electrically coupled with the interconnect pathways 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

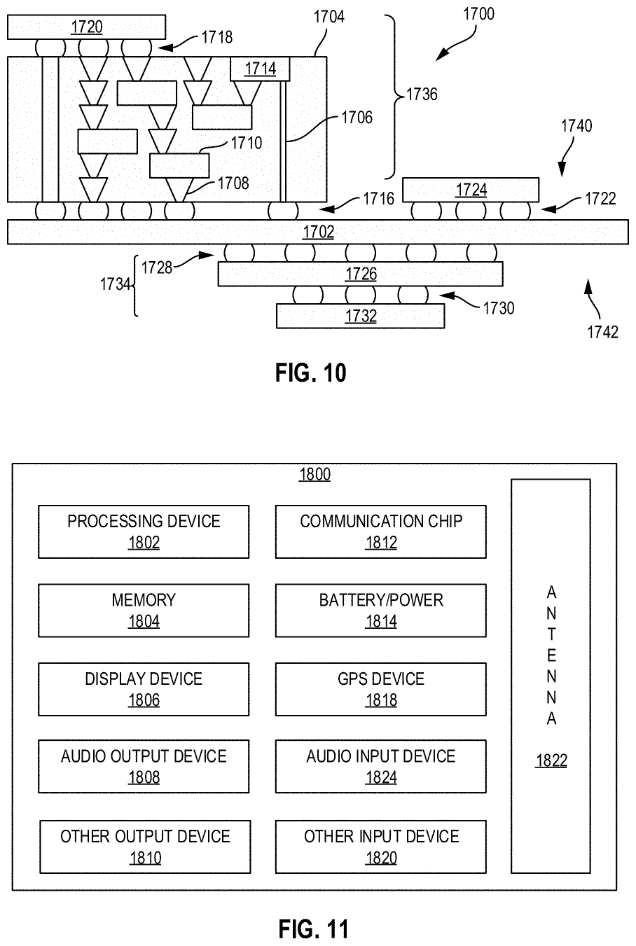

FIG. 10 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8), an IC device (e.g., the IC device 1600 of FIG. 9), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a mobile computing device (e.g., a hand-held, portable or mobile electrical device, such as a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.

Example 1 is a microelectronic assembly, including: a bridge structure having a surface; a first die coupled to the surface of the bridge structure by first interconnects, wherein the first die at least partially overlaps the bridge structure and is non-rectilinear to the bridge structure; and a second die coupled to the surface of the bridge structure by second interconnects, wherein the second die at least partially overlaps the bridge structure.

Example 2 may include the subject matter of Example 1, and may further specify that the second die is non-rectilinear to the bridge structure.

Example 3 may include the subject matter of Example 1, and may further specify that the second die is non-rectilinear to the first die.

Example 4 may include the subject matter of Example 1, and may further specify that the bridge structure is a double-sided die.

Example 5 may include the subject matter of Example 1, and may further specify that the bridge structure is an active interposer having first conductive contacts on a first surface and second conductive contacts on an opposing second surface.

Example 6 may include the subject matter of Example 1, and may further specify that the bridge structure is a passive interposer having a plurality of through silicon vias.

Example 7 may include the subject matter of Example 1, and may further specify that the bridge structure has n-number of sides and n-number of dies coupled to the bridge structure, and wherein at least one individual die of the n-number of dies is non-rectilinear to another individual die of the n-number of dies.

Example 8 may include the subject matter of Example 1, and may further specify that the bridge structure has n-number of sides and (n+1)-number of dies coupled to the bridge structure, and wherein at least one individual die of the (n+1)-number of dies is non-rectilinear to another individual die of the (n+1)-number of dies.

Example 9 may include the subject matter of Example 1, and may further specify that the first die is rectilinear to the second die.

Example 10 may include the subject matter of Example 1, and may further include: a third die coupled to the surface of the bridge structure by third interconnects, wherein a footprint of the third die is wholly within a footprint of the bridge structure.

Example 11 may include the subject matter of Example 10, and may further specify that the third die is a die stack.

Example 12 is a microelectronic assembly, including: a package substrate having a first surface and an opposing second surface; a bridge structure having a first surface and an opposing second surface on the second surface of the package substrate, wherein the first surface of the bridge structure is coupled to the second surface of the package substrate; and a first die on the second surface of the bridge structure and partially overlapping the bridge structure, wherein the first die is coupled to the second surface of the bridge structure by first interconnects and coupled to the second surface of the package substrate by second interconnects, and wherein the first die is non-rectilinear to the bridge structure.

Example 13 may include the subject matter of Example 12, and may further specify that the bridge structure is rectangular.

Example 14 may include the subject matter of Example 12, and may further specify that the bridge structure is non-rectangular.

Example 15 may include the subject matter of Example 12, and may further specify that the first die is rectangular.

Example 16 may include the subject matter of Example 12, and may further specify that the first die is non-rectangular.

Example 17 may include the subject matter of Example 12, and may further specify that the package substrate is rectangular.

Example 18 may include the subject matter of Example 12, and may further specify that the package substrate is non-rectangular.

Example 19 may include the subject matter of Example 12, and may further specify that the first die overlaps the bridge structure by a maximum distance of between Example 0.5 millimeters and 20 millimeters.

Example 20 may include the subject matter of Example 12, and may further specify that the bridge structure is at least partially in a recess in the package substrate.

Example 21 may include the subject matter of Example 12, and may further specify that the first interconnects or the second interconnects include solder.

Example 22 may include the subject matter of Example 12, and may further specify that the first interconnects or the second interconnects include an anisotropic conductive material.

Example 23 may include the subject matter of Example 12, and may further specify that the first interconnects or the second interconnects include plated interconnects.

Example 24 is a computing device, including: a microelectronic assembly, including: a package substrate having a first surface and an opposing second surface; a bridge structure having a first surface and an opposing second surface, wherein the bridge structure is embedded in a first dielectric layer, and wherein the first surface of the bridge structure is coupled to the second surface of the package substrate; a first die having a first surface and an opposing second surface, wherein the first die is embedded in a second dielectric layer on the first dielectric layer, wherein the first die at least partially overlaps the bridge structure, wherein the first surface of the first die is coupled to the second surface of the bridge structure by first interconnects, and wherein the first die is non-rectilinear to the bridge structure; and a second die having a first surface and an opposing second surface, wherein the second die is embedded in the second dielectric layer, and wherein the first surface of the second die is coupled to the second surface of the bridge structure by second interconnects.

Example 25 may include the subject matter of Example 24, and may further specify that the second die is non-rectilinear to the bridge structure.

Example 26 may include the subject matter of Example 24, and may further specify that the second die is non-rectilinear to the first die.

Example 27 may include the subject matter of Example 24, and may further specify that the first die or the second die is a central processing unit.

Example 28 may include the subject matter of Example 24, and may further specify that the first die or the second die includes a memory device.

Example 29 may include the subject matter of Example 24, and may further specify that the first die or the second die is a high bandwidth memory device.

Example 30 may include the subject matter of Example 24, and may further specify that the package substrate is a printed circuit board.

Example 31 may include the subject matter of Example 24, and may further specify that the computing device is a server.

Example 32 may include the subject matter of Example 24, and may further specify that the computing device is a mobile computing device.

Example 33 may include the subject matter of Example 24, and may further specify that the computing device is a wearable computing device.

Example 34 may include the subject matter of Example 24, and may further specify that the first surface of the first die is coupled to the second surface of the package substrate by third interconnects.

Example 35 may include the subject matter of Example 34, and may further specify that the third interconnects include a conductive pillar.

Example 36 may include the subject matter of Example 24, and may further specify that the first surface of the second die is coupled to the second surface of the package substrate by fourth interconnects.

Example 37 may include the subject matter of Example 36, and may further specify that the fourth interconnects include a conductive via.

Example 38 is a method of manufacturing a microelectronic assembly, including: forming first interconnects between a bridge structure and a first die, wherein the bridge structure has a first surface with first conductive contacts and an opposing second surface with second conductive contacts, wherein the first die has a surface with conductive contacts, wherein the first interconnects couple the second conductive contacts of the bridge structure to the conductive contacts of the first die, and wherein the first die at least partially overlaps the bridge structure and is non-rectilinear to the bridge structure; and forming second interconnects between the bridge structure and a second die, wherein the second die has a surface with conductive contacts, wherein the second interconnects couple the second conductive contacts of the bridge structure to the conductive contacts of the second die, and wherein the second die at least partially overlaps the bridge structure.

Example 39 may include the subject matter of Example 38, and may further specify that the second die is non-rectilinear to the bridge structure.

Example 40 may include the subject matter of Example 38, and may further specify that the second die is non-rectilinear to the first die.

Example 41 may include the subject matter of Example 38, and may further include: forming third interconnects between the bridge structure and a package substrate, wherein the package substrate has a surface with conductive contacts, wherein the third interconnects couple the first conductive contacts of the bridge structure to the conductive contacts of the package substrate.

Example 42 may include the subject matter of Example 41, and may further include: forming fourth interconnects between the first die and the package substrate, wherein the fourth interconnects couple the conductive contacts of the first die to the conductive contacts of the package substrate.

Example 43 may include the subject matter of Example 42, and may further include: forming fifth interconnects between the second die and the package substrate, wherein the fifth interconnects couple the conductive contacts of the second die to the conductive contacts of the package substrate.

1. A microelectronic assembly, comprising:
a bridge structure having a surface;
a first die coupled to the surface of the bridge structure by first interconnects, wherein the first die at least partially overlaps the bridge structure and is non-rectilinear to the bridge structure; and
a second die coupled to the surface of the bridge structure by second interconnects, wherein the second die at least partially overlaps the bridge structure.

2. The microelectronic assembly of claim 1, wherein the second die is non-rectilinear to the bridge structure.

3. The microelectronic assembly of claim 1, wherein the second die is non-rectilinear to the first die.

4. The microelectronic assembly of claim 1, wherein the bridge structure is a double-sided die.

5. The microelectronic assembly of claim 1, wherein the bridge structure is an active interposer having first conductive contacts on a first surface and second conductive contacts on an opposing second surface.

6. The microelectronic assembly of claim 1, wherein the bridge structure is a passive interposer having a plurality of through silicon vias.

7. The microelectronic assembly of claim 1, wherein the bridge structure has n-number of sides and n-number of dies coupled to the bridge structure, and wherein at least one individual die of the n-number of dies is non-rectilinear to another individual die of the n-number of dies.

8. The microelectronic assembly of claim 1, wherein the bridge structure has n-number of sides and (n+1)-number of dies coupled to the bridge structure, and wherein at least one individual die of the (n+1)-number of dies is non-rectilinear to another individual die of the (n+1)-number of dies.

9. The microelectronic assembly of claim 1, wherein the first die is rectilinear to the second die.

10. The microelectronic assembly of claim 1, further comprising:
a third die coupled to the surface of the bridge structure by third interconnects, wherein a footprint of the third die is wholly within a footprint of the bridge structure.

11. The microelectronic assembly of claim 10, wherein the third die is a die stack.

12. A microelectronic assembly, comprising:
a package substrate having a first surface and an opposing second surface;
a bridge structure having a first surface and an opposing second surface, wherein the first surface of the bridge structure is coupled to the second surface of the package substrate; and
a first die on the second surface of the bridge structure and partially overlapping the bridge structure, wherein the first die is coupled to the second surface of the bridge structure by first interconnects and coupled to the second surface of the package substrate by second interconnects, and wherein the first die is non-rectilinear to the bridge structure.

13. The microelectronic assembly of claim 12, wherein the bridge structure is rectangular.

14. The microelectronic assembly of claim 12, wherein the bridge structure is non-rectangular.

15. The microelectronic assembly of claim 12, wherein the package substrate is non-rectangular.

16. The microelectronic assembly of claim 12, wherein the first die overlaps the bridge structure by a maximum distance of between 0.5 millimeters and 20 millimeters.

17. The microelectronic assembly of claim 12, wherein the bridge structure is at least partially in a recess in the package substrate.

18. A computing device, comprising:
a microelectronic assembly, comprising:
a package substrate having a first surface and an opposing second surface;
a bridge structure having a first surface and an opposing second surface, wherein the bridge structure is embedded in a first dielectric layer, and wherein the first surface of the bridge structure is coupled to the second surface of the package substrate;
a first die having a first surface and an opposing second surface, wherein the first die is embedded in a second dielectric layer on the first dielectric layer, wherein the first die at least partially overlaps the bridge structure, wherein the first surface of the first die is coupled to the second surface of the bridge structure by first interconnects, and wherein the first die is non-rectilinear to the bridge structure; and
a second die having a first surface and an opposing second surface, wherein the second die is embedded in the second dielectric layer, and wherein the first surface of the second die is coupled to the second surface of the bridge structure by second interconnects.

19. The computing device of claim 18, wherein the first die or the second die is a central processing unit.

20. The computing device of claim 18, wherein the first die or the second die includes a memory device.

21. The computing device of claim 18, wherein the first die or the second die is a high bandwidth memory device.

22. A method of manufacturing a microelectronic assembly, comprising:
forming first interconnects between a bridge structure and a first die, wherein the bridge structure has a first surface with first conductive contacts and an opposing second surface with second conductive contacts, wherein the first die has a surface with conductive contacts, wherein the first interconnects couple the second conductive contacts of the bridge structure to the conductive contacts of the first die, and wherein the first die at least partially overlaps the bridge structure and is non-rectilinear to the bridge structure; and
forming second interconnects between the bridge structure and a second die, wherein the second die has a surface with conductive contacts, wherein the second interconnects couple the second conductive contacts of the bridge structure to the conductive contacts of the second die, and wherein the second die at least partially overlaps the bridge structure.

23. The method of claim 22, wherein the second die is non-rectilinear to the bridge structure.

24. The method of claim 22, further comprising:
forming third interconnects between the bridge structure and a package substrate, wherein the package substrate has a surface with conductive contacts, wherein the third interconnects couple the first conductive contacts of the bridge structure to the conductive contacts of the package substrate.

25. The method of claim 24, further comprising:
forming fourth interconnects between the first die and the package substrate, wherein the fourth interconnects couple the conductive contacts of the first die to the conductive contacts of the package substrate.
